(19) United States
(12) Patent Application Publication
(10) Pub. No.: US 2009/0068829 A1
(43) Pub. Date: Mar. 12, 2009

(54) METHOD OF MANUFACTURING SEMICONDUCTOR DEVICE

(75) Inventor: In No Lee, Kyeongki-do (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Icheon-Si (KR)

(21) Appl. No.: 11/964,290

(22) Filed: Dec. 26, 2007

(30) Foreign Application Priority Data
Sep. 6, 2007 (KR) 10-2007-0090294

(51) Int. Cl. H01L 21/441

(52) U.S. Cl. 438/594; 257/E21.477

(57) ABSTRACT

A method of manufacturing a semiconductor device comprising forming a conductive layer on a semiconductor substrate; forming a metal layer on the conductive layer; performing a first etching process for patterning the metal layer on a first area to form first metal layer patterns at relatively wide intervals until the conductive layer of the first area is exposed; performing a second etching process for forming an etching-obstructing layer on the first area and patterning the metal layer on a second area to form second metal layer patterns at relatively narrow intervals until the conductive layer of the second area is exposed; removing the etching-obstructing layer; and removing an exposed area of the conductive layer to form a conductive pattern.

### CROSS-REFERENCE TO RELATED APPLICATION

The priority of Korean Patent Application No. 2007-0090294, filed on Sep. 6, 2007, the disclosure of which is incorporated herein by reference in its entirety, is claimed.

### BACKGROUND OF THE INVENTION

The invention relates to a method of manufacturing a semiconductor device and, more particularly, relates to a method of manufacturing a semiconductor device which can improve a loading effect according to a pattern density during a gate etching process.

In a flash memory device, data are stored through a program operation in which electrons are injected to a floating gate through Fowler-Nordheim (F-N) tunneling or an erase operation in which electrons are discharged from the floating gate through F-N tunneling. In such flash memory device, a drain select line, a source select line, and a plurality word lines crossing an isolation layer are formed, each of the word lines being disposed between the drain select line and the source select line.

Below, a method of forming the word lines and the select lines is briefly illustrated. First of all, a tunnel insulating layer and a first polysilicon layer for a floating gate are formed on a semiconductor substrate and the first polysilicon layer is then patterned in one direction (the bit-line direction) through an etching process utilizing a mask. Subsequently, an oxide-nitride-oxide (ONO) dielectric layer, a second polysilicon layer, a tungsten silicide (WSiₓ) layer, and a gate mask are sequentially formed on the semiconductor substrate including the first polysilicon layer pattern. Before forming the second polysilicon layer, the dielectric layer on predetermined areas for forming select lines is partially or entirely removed by an etching layer to expose the first polysilicon layer pattern.

Then, the gate mask is patterned through an etching process utilizing a mask. At this time, a portion of the gate mask may be etched during the etching process. Subsequently, the tungsten silicide layer, the second polysilicon layer, the dielectric layer, the first polysilicon layer pattern, and the tunnel insulating layer are sequentially patterned through an etching process in which the gate mask pattern is utilized as an etching mask. At this time, a floating gate consisting of the first polysilicon layer pattern is formed, and a control gate consisting of the second polysilicon layer pattern and the tungsten silicide layer pattern is formed. From this, a gate pattern including the tunnel insulating layer, the floating gate, the dielectric layer, the control gate, and the gate mask pattern is formed, and a control gate of a cell formed on another string is connected to the gate pattern to form the word line. On the other hand, select lines (a source select line and a drain select line) including the tunnel insulating layer, the first polysilicon layer pattern, the second polysilicon layer pattern connected electrically to the first polysilicon layer pattern, the tungsten silicide layer pattern, and the gate mask pattern are formed on both periphery portions of each of the word lines.

In general, when the tungsten silicide layer is etched for patterning the gate, a process for etching the tungsten silicide layer is performed until the second polysilicon layer between the predetermined areas for forming the select lines is exposed. However, in a flash memory device, a distance between the select lines is larger than between the word lines, and a distance between the select line and the adjacent word line is larger than that between the word lines and smaller than that between the select lines. Accordingly, during the process for etching the tungsten silicide layer, when the second polysilicon layer between the predetermined areas for forming the select lines is exposed by a loading effect caused by a pattern density, the tungsten silicide layers between the predetermined areas for forming the word lines and between the word line and the select line are not completely etched, but some of the tungsten silicide layer remains. In this case, to remove the remained tungsten silicide layer, an over-etching process should be performed. However, there are problems that if a thickness of the layer to be etched is small, the tungsten silicide layer between the predetermined areas for forming the word lines remains and if a thickness of the layer to be etched is large, the dielectric layer between the predetermined areas for forming the select line is attacked.

In addition, in a case where, after an over-etching process, the tungsten silicide layer remains between the predetermined areas for forming the word lines, when an etching process for the second polysilicon layer is performed under a condition of a high etching selection ratio with respect to an oxide layer for halting an etching on a surface of the dielectric layer, the remaining tungsten silicide layer is not sufficiently removed and this causes the word line bridge. After the over etching process, on the other hand, if the dielectric layer between the predetermined areas for forming the select lines is opened, in the step of etching the second polysilicon layer between the predetermined areas for forming the subsequent word lines, the first polysilicon layer between the predetermined areas for forming the select lines is lost so that an active area of the semiconductor substrate is attacked.

### SUMMARY OF THE INVENTION

The invention provides a method of manufacturing a semiconductor device in which when the gate etching process is performed, the etching-obstructing layer is formed on an interface of the conductive layer on an area having a low density metal layer pattern and the metal layer remaining on an area having a high density metal layer pattern so as to change an etching selection ratio with respect to the conductive layer on the area having the low density metal layer pattern after patterning the metal layer. Accordingly, the invention has the advantage in that the loading effect according to the pattern density is improved to enable a height difference between the area having the high pattern density and the area having the low pattern density to be minimized.

A method of manufacturing a semiconductor device according to one embodiment of the invention comprises forming a conductive layer on a semiconductor substrate; forming a metal layer on the conductive layer; performing a first etching process to pattern the metal layer on a first area to form first metal layer patterns at first relatively wide intervals until the conductive layer of the first area is exposed; performing a second etching process to form an etching-obstructing layer on the first area and patterning the metal layer on a second area to form second metal layer patterns at relatively narrow intervals with respect to the first metal layer patterns until the conductive layer of the second area is exposed; removing the etching-obstructing layer; and removing an exposed area of the conductive layer to form a conductive pattern.

In the above method, the metal layer preferably comprises a metal silicide layer. The metal silicide layer preferably comprises a tungsten silicide (WSiₓ) layer, and the conductive layer preferably comprises a polysilicon layer.

The metal layer remains on the second area on which the second metal layer patterns are formed at narrow intervals after the first etching process. Also, the etching obstruction layer preferably comprises a silicon oxide (SiO₂) layer formed by a reaction of the polysilicon layer with oxygen (O₂).

The second etching process is preferably performed under conditions of pressure of 4 mT to 10 mT, source power of 500 W to 1,200 W, and bias power of 40 W to 200 W. The second etching process is preferably performed under the conditions of oxygen (O₂) flow at a rate of 40 standard cubic centimeter per minute (sccm) to 200 sccm, nitrogen trifluroride (NF₃) flow at a rate of 20 sccm to 80 sccm and lower than the oxygen flow rate and chlorine (Cl₂) at a flow rate of 40 sccm to 120 sccm. In addition, the second etching process preferably further utilizes nitrogen (N₂) at a flow rate of 100 sccm to 200 sccm and argon (Ar) at a flow rate of 50 sccm to 200 sccm.

The etching-obstructing layer is preferably removed by an etching recipe having an etching selection ratio with respect to the etching-obstructing layer, which is higher than that with respect to the conductive layer. The method of manufacturing a semiconductor device of the invention preferably further comprises forming a gate insulating layer between the conductive layer and the semiconductor substrate.

A method of manufacturing a flash memory device according to another embodiment of the invention comprises providing a semiconductor substrate on which a tunnel oxide layer, a first conductive layer, and a second conductive layer are stacked; forming a metal layer on the second conductive layer; performing a first etching process for patterning the metal layer on a first area to form first metal layer patterns at first, relatively wide intervals until the second conductive layer of the first area is exposed; performing a second etching process for forming an etching-obstructing layer on the first area and patterning the metal layer on a second area to form second metal layer patterns at second relatively narrow intervals until the second conductive layer of the second area is exposed; removing the etching-obstructing layer; removing an exposed area of the second conductive layer to form a second conductive layer pattern; patterning the dielectric layer; and patterning the first conductive layer to form a first conductive layer pattern.

In the above method, the first conductive layer and the second conductive layer are preferably formed of polysilicon layers, and the metal layer preferably comprises a metal silicide layer. In addition, the metal silicide layer preferably comprises a tungsten silicide (WSiₓ) layer.

The metal layer preferably remains on the second area on which the second metal layer patterns are formed at second, relatively narrow intervals after the first etching process. In addition, the first area on which the metal layer patterns are formed at wide intervals is preferably a predetermined area for forming word lines and the second area on which the metal layer patterns are formed at narrow intervals is preferably a predetermined area for forming select lines. The etching obstruction layer preferably comprises a silicon oxide (SiO₂) layer formed by a reaction of the polysilicon layer with oxygen (O₂).

The second etching process is preferably performed under the conditions of pressure of 4 mT to 10 mT, source power of 500 W to 1,200 W and bias power of 40 W to 200 W. In addition, the second etching process is preferably performed under conditions of oxygen (O₂) flow at a rate of 40 standard cubic centimeter per minute (sccm) to 200 sccm, nitrogen trifluroride (NF₃) flow at a rate of 20 sccm to 80 sccm which is relatively less than the flow rate of oxygen, and chlorine (Cl₂) at a flow rate of 40 sccm to 120 sccm. Also, the second etching process preferably further utilizes nitrogen (N₂) at a flow rate of 100 sccm to 200 sccm and argon (Ar) at a flow rate of 50 sccm to 200 sccm.

For removing the etching-obstructing layer, an etching recipe having an etching selection ratio with respect to the etching-obstructing layer, which is higher than that with respect to the second conductive layer, is preferably utilized. The dielectric layer preferably comprises a stack layer including oxide layer, a nitride layer, and an oxide layer. To pattern the second conductive layer, an etching recipe having an etching selection ratio with respect to the second conductive layer, which is higher than that with respect to the oxide layer, is preferably utilized.

The method of manufacturing a flash memory device of the invention preferably further comprises forming a gate mask pattern on the metal layer, the gate mask pattern having a stack structure preferably including a first hard mask pattern, an amorphous carbon layer pattern, and a second hard mask pattern. The metal layer, the second conductive layer, the dielectric layer, and the first conductive layer are preferably patterned through an etching process in which the amorphous carbon layer pattern is used as the etching mask, or the second conductive layer, the dielectric layer, and the first conductive layer are preferably patterned through an etching process in which the first hard mask pattern is used as the etching mask, after removing the amorphous carbon layer pattern.

### BRIEF DESCRIPTION OF THE DRAWINGS

The above and other features and advantages of the invention will become readily apparent by reference to the following detailed description when considered in conjunction with the accompanying drawings wherein:

FIG. 1 is a layout of a flash memory device according to one embodiment of the invention; and

FIG. 2A to FIG. 2F are sectional views taken along the line A-A′ in FIG. 1 and showing a process for manufacturing the flash memory device of FIG. 1.

### DESCRIPTION OF SPECIFIC EMBODIMENTS

Hereinafter, the preferred embodiments of the invention are explained in more detail with reference to the accompanying drawings. However, the embodiments of the invention may be modified in various ways and the scope of the invention is not to be limited to the illustrated embodiment. The description herein is provided for illustrating more completely to those skilled in the art.

The invention is not limited to a process of manufacturing a NAND flash memory, but is applicable to technology for manufacturing semiconductor devices such as dynamic random access memory (DRAM) and the static random access memory (SRAM). In the following description, the NAND flash memory device is illustrated as one example.

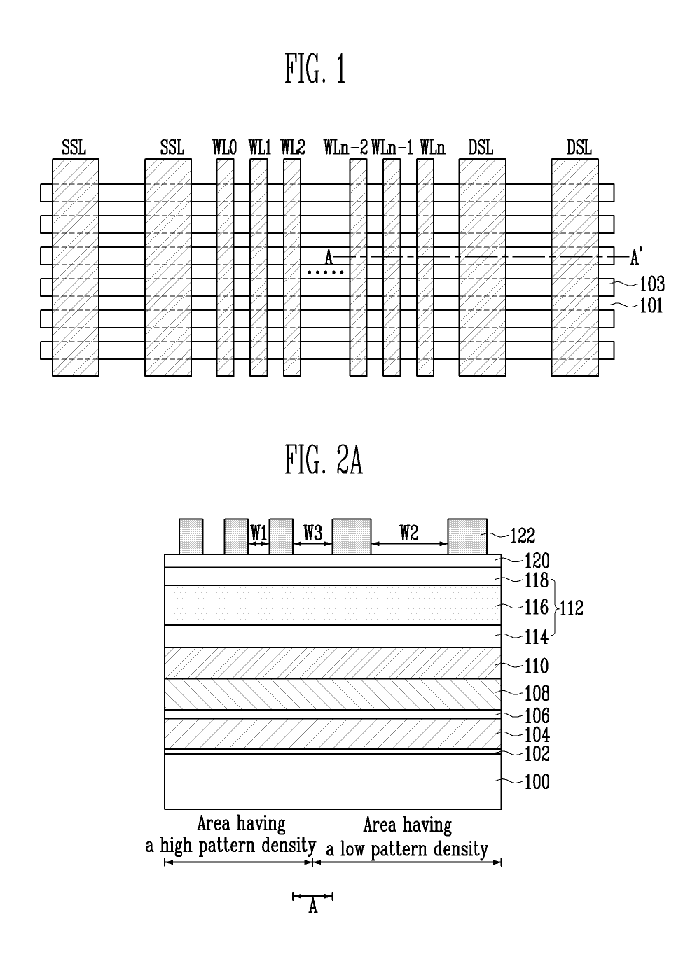

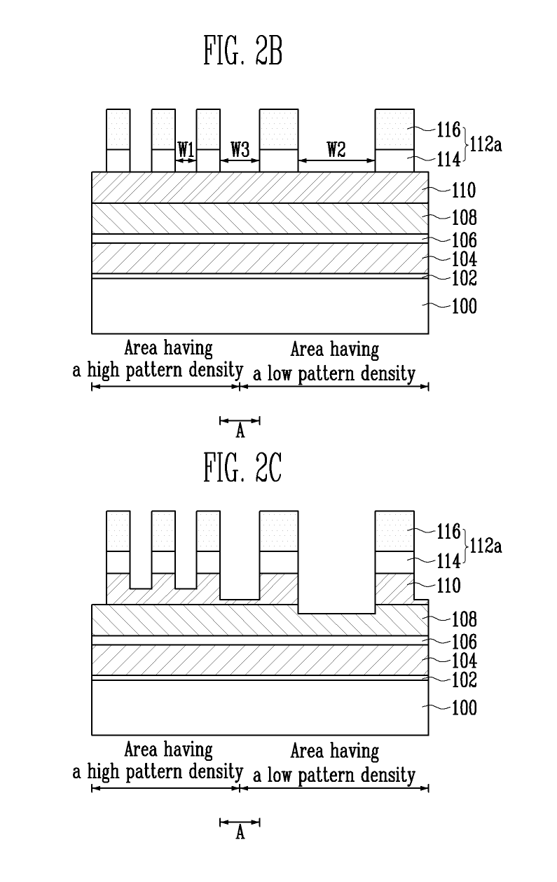

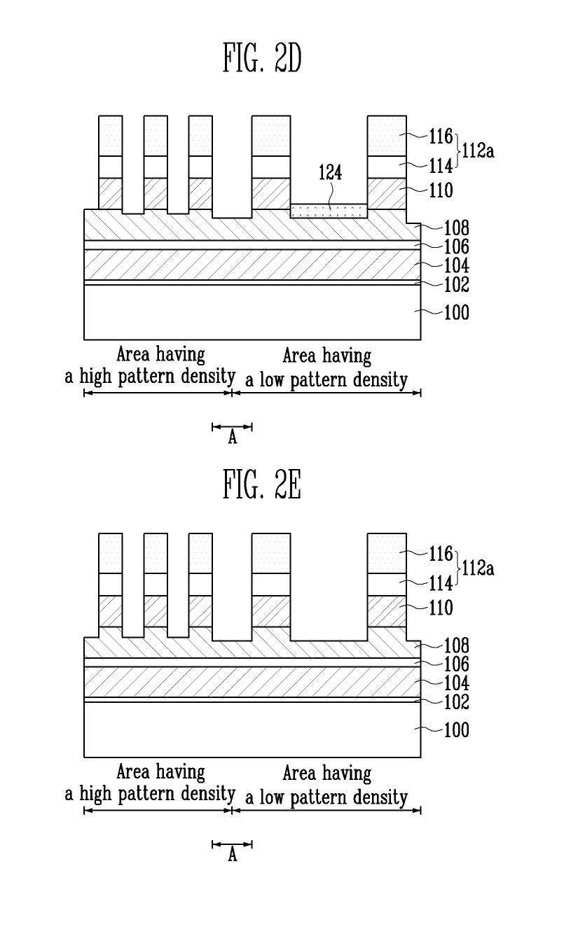

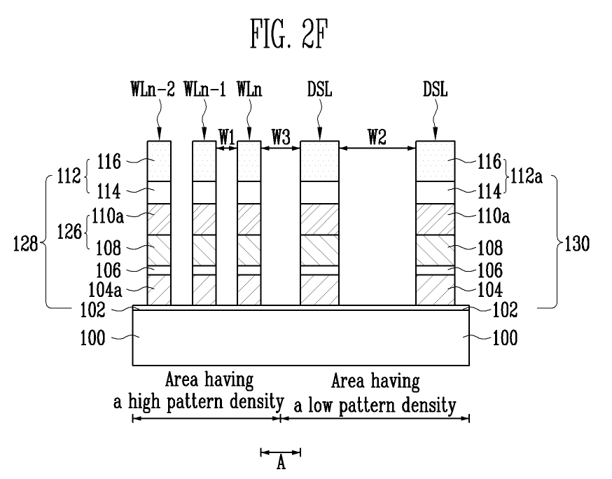

FIG. 1 is a layout of a flash memory device according to one embodiment of the invention and FIG. 2A to FIG. 2F are sectional views taken along the line A-A′ in FIG. 1 and showing a process for manufacturing the flash memory device of FIG. 1.

Referring to FIG. 1, a plurality of isolation layers 101 are formed in parallel on a cell area of a semiconductor substrate. An area of the semiconductor substrate between the isolation layers 101 is defined as an active area by the isolation layer 101. A plurality of select lines DSL and SSL and a plurality of word lines WLo to WLn crossing the isolation layers 101 are formed on the semiconductor substrate. At this time, a distance between the select lines (between DSL and DSL or between SSL and SSL) is larger than that between the word lines WLo to WLn. In addition, a distance between the select line DLS or SSL and the adjacent word line WLo or WLn is larger than that between the word lines WLo to WLn and smaller than that between the select lines (between DSL and DSL or between SSL and SSL). Accordingly, the area on which the word lines WLo to WLn are formed has a high pattern density, while the area on which the select lines DLS or SSL are formed has a low pattern density.

Referring to FIG. 2A, a tunnel insulating layer 102 and a first conductive layer 104 are sequentially formed on the semiconductor substrate 100 having the area with a high pattern density and the area with a low pattern density. In a conventional flash memory device, the area having a low pattern density can be defined as a first area on which the metal layer is patterned such that metal layer patterns are disposed at wide intervals and the area having a high pattern density can be defined as a second area on which the metal layer is patterned such that metal layer patterns are disposed at intervals which are narrower than that between the metal layer patterns in the first area. The select lines DSL and SSL will be formed on the first area later and the word lines will be formed on the second area. The method of the invention is applicable to the area on which the drain select line will be formed as well as the area on which the source select line will be formed. In the following description, however, the area having a low pattern density is regarded as the area on which the drain select line will be formed.

Here, the tunnel insulating layer 102 is typically formed of a silicon oxide (SiO₂) layer. In this case, the tunnel insulating layer can be formed through an oxidation process. In a semiconductor device such as a dynamic random access memory (DRAM), the tunnel insulating layer 102 is formed of a gate insulating layer. In addition, the first conductive layer 104 acts as a floating gate of the flash memory device and is typically formed of a polysilicon layer. In a semiconductor device such as the DRAM, the first conductive layer 104 is utilized as a gate electrode.

Then, the first conductive layer 104 is patterned in one direction (bit line direction) through an etching process in which a mask (not shown) is utilized. Here, the photoresist pattern may be used as the mask. In this case, the photoresist is applied on the first conductive layer 104 and the photoresist is then patterned through an exposure process and a developing process to form the photoresist pattern.

Subsequently, the exposed tunnel insulating layer 102 on the isolation area is etched, and the exposed semiconductor substrate 100 is then etched to a certain depth to form a trench (not shown). Then, insulation material is deposited to fill the trench and a planarization process is then performed so that the insulating layer remains in only the trench to form the isolation layer 101 (in FIG. 1) in the trench. At this time, active areas 103 (in FIG. 1) and isolation areas are defined by the isolation layer 101 (in FIG. 1)

Subsequently, a dielectric layer 106, a second conductive layer 108, a metal layer 110, a gate mask layer 112, and an anti-reflective coating (ARC) layer 120 are sequentially formed on the first conductive layer pattern 104. The dielectric layer 106 may be formed of a stack layer (ONO) consisting of an oxide layer, a nitride layer, and an oxide layer. The second conductive layer 108 acts as a control gate of the flash memory device and may be formed of a polysilicon layer. The metal layer 110 is used for lowering a resistance of the control gate or the gate electrode to be formed later. This metal layer may be formed of a metal silicide layer and, preferably, may be formed of a tungsten silicide (WSiₓ) layer. When the tungsten silicide (WSiₓ) layer is formed, monosilane (MS) or dichlorosilane (DCS) can be used as the source.

In addition, the gate mask layer 112 may be formed of a stack layer consisting of a first hard mask 114, an amorphous carbon layer 116, and a second hard mask 118. At this time, the first hard mask 114 may be formed of an oxide layer and the second hard mask 118 may be formed of a silicon oxide nitride (SiON) layer. The anti-reflective coating (ARC) layer 120 is formed for preventing the light being diffusely reflected during a photolithography process. However, there may be no need to form this anti-reflective coating layer. In the semiconductor device such as the DRAM, on the other hand, the steps for forming the dielectric layer 106 and the second conductive layer 108 may be omitted, and the metal layer 110, the gate mask layer 112, and the anti-reflective coating layer 120 are formed on the first conductive layer 104. At this time, this anti-reflective coating layer 120 may not be formed.

Subsequently, an etching mask 122 to be used as a mask during a gate etching process is formed on the anti-reflective coating layer 120. Specifically, the etching mask 122 is formed such that a distance between patterns of the etching mask 122 on the area having a high pattern density (that is, the predetermined area for forming the word lines WLo to WLn), is relatively narrow (hereinafter, referred to as “the first width W1”). On the other hand, a distance between patterns of the etching mask 122 on the area having a low pattern density (that is, the predetermined area for forming the select lines DSL and SSL), is the second width W2 larger than the first width W1. In addition, a distance between patterns of the etching mask 122 on a border portion A between the area having a low pattern density and the area having a high pattern density (that is, an area between the predetermined area for forming the select lines DSL or SSL and the predetermined area for forming the word lines WLo or WLn) is a third width W3 larger than the first width W1, but smaller than the second width W2. The etching mask 122 may be formed of photoresist patterns. In this case, photoresist can be applied on the anti-reflective coating layer 120 and then patterned through an exposure process and a developing processes to form the photoresist patterns.

Referring to FIG. 2B, the anti-reflective coating layer 120 and the gate mask layer 112 are patterned through an etching process utilizing the etching mask 122. During the etching process, at this time, the etching mask 122, the anti-reflective coating layer 120, and the second hard mask 118 of the gate mask layer 112 are etched and removed, and a portion of the amorphous carbon layer 116 can be etched. From this, the gate mask pattern 112a formed on the area having a high pattern density has the first width W1, the gate mask pattern 112a formed on the area having a low pattern density has the second width W2 larger than the first width W1, and the gate mask pattern 112a formed on the boarder portion A has the third width W3 larger than the first width W1, but smaller than the second width W2.

Referring to FIG. 2C, the metal layer 110 is patterned through an etching process in which the gate mask patterns 112 are utilized as the etching mask until the second conductive layer 108 formed on the area having the low pattern density is exposed. In one embodiment of the invention, if the metal layer 110 is formed of a tungsten silicide (WSiₓ) layer, a dry etching process using fluorine-based etching gas is preferably performed as the etching process.

After the process for etching the metal layer 110, the metal layer 110 formed on the area having the low pattern density is completely patterned so that the second conductive layer 108 is exposed, while the metal layer 110 with a certain thickness remains on the border portion A and the area having the high pattern density due to a loading effect caused by the pattern density. In particular, the metal layer 110 remaining on the area having the high pattern density is thicker than that remaining on the border area A.

If the metal layer 110 remains as described above, a bridge can be generated according to a fault of the gate pattern or the semiconductor substrate 100 may be attacked after performing the subsequent gate etching process, and so the metal layer should be removed.

Referring to FIG. 2D, the etching process is performed such that etching for the area having the low pattern density is stopped and the metal layer 110 remaining on the area having the high pattern density and the border portion A is patterned. That is, the etching process is performed such that an etching for the area having the low pattern density is stopped and the area having the high pattern density can be etched up to a predetermined thickness through the normal etching process.

For achieving the above etching state, the etching process is illustratively performed under the conditions of a low pressure of 4 mT to 10 mT, a relatively high source power of 500 W to 1,200 W, a lowered bias power of 40 W to 200 W, oxygen (O₂) at a flow rate within a range of 40 standard cubic centimeter per minute (sccm) to 200 sccm, nitrogen trifluroride (NF₃) at a flow rate of 20 sccm to 80 sccm which is lower than the flow rate of oxygen, and chlorine (Cl₂) at a flow rate of 40 sccm to 120 sccm. In the above case, the polysilicon layer which is the exposed second conductive layer 108 on the area having the low pattern density reacts with oxygen (O₂) so that an etching-obstructing layer 124 formed of a silicon oxide (SiO₂) layer is formed on an interface of the second conductive layer 108 and an etching process is stopped by this etching-obstructing layer. On the other hand, the area having the high pattern density and the border portion A have a relatively small opened area so that little residual product is produced. Accordingly, the etching-obstructing layer is not formed and the normal etching process can be performed to etch the remained metal layer 110.

Due to the etching-obstructing layer 124 formed on the interface of the second conductive layer 108 on the area having the low pattern density when the etching process for the remained metal layer 110 is performed, an etching selection ratio of the area having the low pattern density is different from that of the area having the high pattern density and the border portion A so that an etching process can be stopped on the area having the low pattern density, while the etching process can be normally performed on the area having the high pattern density and the border portion A. Accordingly, the second conductive layer 108 formed on the area having the high pattern density and the border portion A is exposed.

As described above, by using the characteristic of different etching selection ratio when the etching process utilizing the etching-obstructing layer 124 formed on the interface of the second conductive layer 108 on the area having the low pattern density is performed, it is possible to minimize topology between the area having the low pattern density and the area having the high pattern density and to prevent a bridge from being generated between the word lines which will be formed later.

In the meantime, nitrogen (N₂) at a flow rate of 10 standard cubic centimeter per minute (sccm) to 200 sccm and argon (Ar) at a flow rate of 50 sccm to 200 sccm are preferably further utilized in the etching process so that generation of the undercut caused by excessive oxygen (O₂) is prevented to protect the gate side walls.

However, the etching-obstructing layer 124 still remains on the area having the low pattern density, and this etching-obstructing layer should be removed prior to patterning the second conductive layer 108.

Referring to FIG. 2E, an etching process is performed for removing the etching-obstructing layer (124 in FIG. 2D) formed on the interface of the second conductive layer 108 on the area having the low pattern density. In the etching process, an etching recipe having an etching selection ratio with respect to the etching-obstructing layer (124 in FIG. 2D) higher than that with respect to the second conductive layer 108 is preferably utilized so as to prevent the dielectric layer 106 below the etching-obstructing layer from being attacked during a process for removing the etching-obstructing layer (124 in FIG. 2D). According to one embodiment of the invention, since the etching-obstructing layer (124 in FIG. 2D) is formed of a silicon oxide (SiO₂) layer and the second conductive layer 108 is formed of a polysiliocn layer, it is preferable to perform the etching process for removing the etching-obstructing layer 124 using the etching recipe having an etching selection ratio with respect to the oxide layer higher than that with the polysiliocn layer.

By the above process, the etching-obstructing layer (124 in FIG. 2D) is removed. In this process, the second conductive layer 108 on the area having the high pattern density and the area having the low pattern density can be etched up to a certain thickness. However, a surface of the dielectric layer 106 is not exposed.

On the other hand, even though the metal layer 110 remains on the border portion A, all the remaining metal layer is etched during the etching process for removing the etching-obstructing layer 124. At this time, the silicide residue is removed together with the metal layer.

Referring to FIG. 2F, the exposed second conductive layer 108 on the area having the high pattern density and the area having the low pattern density is patterned through an etching process in which the gate mask patterns 112a and the metal layer patterns 110a are utilized as the etching mask. In the etching process, at this time, an etching recipe having an etching selection ratio with respect to the second conductive layer 108 higher than that with respect to the oxide layer is preferably utilized so as to prevent the dielectric layer 106 from being attacked during a process for patterning the second conductive layer 108. According to one embodiment of the invention, since the second conductive layer 108 is formed of a polysiliocn layer, it is preferable to perform the process for patterning the second conductive layer 108 using an etching recipe having an etching selection ratio with respect to the polysiliocn layer higher than that with the oxide layer.

By the above process, the dielectric layer 106 is exposed, and an etching on the upper side of the dielectric layer 106 is stopped so that a topology between the area having the high pattern density and the area having the low pattern density is minimized. At this time, a control gate 126 including the second conductive layer 108 and the metal layer pattern 110a is formed on the area having the high pattern density.

Subsequently, the dielectric layer 106 is patterned through an etching process in which the gate mask patterns 112a and the control gate 126 are utilized as the etching mask. From this, a surface of the first conductive layer 104 is exposed. Then, the exposed first conductive layer 104 is patterned through an etching process in which the gate mask patterns 112a and the control gate 126 are utilized as the etching mask. From this, a floating gate 104a consisting of the first conductive layer pattern (not shown) is formed on the area having the high pattern density. At this time, a gate pattern 128 of the memory cell including the tunnel insulating layer 102, the floating gate 104a, the dielectric layer 106, the control gate 126, and the gate mask pattern 112 is formed on the area having the high pattern density. The control gates 126 formed to another string are connected each other to form the word lines WLo to WLn (in the drawing, only WLn-2, WLn-1 and WLn are illustrated). A width between the word lines WLo to WLn is the first width W1.

A gate pattern 130 of a select transistor including the tunnel insulating layer 102, the first conductive layer pattern 104, the dielectric layer 106, the second conductive layer pattern 108, the metal layer pattern 110a, and the gate mask pattern 112 is formed on the area having the low pattern density. The second conductive layer pattern 108 formed on another string is connected to the gate pattern 130 to form the select lines DSL or SSL (in the drawing, only DSL is illustrated). A width between the select lines DSL and DSL or SSL and SSL is the second width W2 larger than the first width W1. In this gate pattern 130 of the select transistor, the first conductive layer pattern 104 and the second conductive layer pattern 108 are electrically connected to each other through a subsequent interconnection process.

And, on the border portion A, a distance between the word line WLo or WLn (only WLn is illustrated in the drawing) and the select line DSL or SSL (only DSL is illustrated in the drawing) adjacent to the word line is the third width W3 larger than the first width W1, but smaller than the second width W2.

In the meantime, in the semiconductor device such as the DRAM, the gate (not shown) including the gate insulating layer, the first conductive layer pattern, the metal layer pattern, and the gate mask are formed on each of the area having the high pattern density and the area having the low pattern density.

As described above, in a case where a gate etching process is performed on the area having the low pattern density using the etching-obstructing layer, a loading effect caused by a difference of the pattern density is improved to minimize a height difference between the area having the high pattern density and the area having the low pattern density, and it is possible to prevent an attack of the semiconductor device and a bridge caused by a pattern fault of the word line from being generated.

For the convenience of illustration, even though the etching process for forming the control gate, the dielectric layer and the floating gate using the amorphous carbon layer pattern 116 of the gate mask pattern 112 as the etching mask is illustrated herein, the invention is not limited thereto. For example, after removing the amorphous carbon layer pattern 116, the control gate, the dielectric layer, and the floating gate can be formed through the etching process utilizing the first hard mask pattern 114 as the etching mask.

In the invention, when the gate etching process is performed, the etching-obstructing layer is formed on an interface of the conductive layer on the area having the low density of the metal layer pattern and the metal layer remained on the area having the high density of the metal layer pattern so as to change an etching selection ratio with respect to the conductive layer on the area having the low density of the metal layer pattern after patterning the metal layer, and so the loading effect according to the pattern density is improved to enable a topology between the area having the high pattern density and the area having the low pattern density to be minimized.

In the invention, since the etching-obstructing layer is formed, the etching selection ratio of the area having the low pattern density differs from that of the area having the high pattern density, and so an etching on the area having the low pattern density is stopped and the area having the high pattern density is etched up to a predetermined thickness through the normal etching process. Consequently, generation of the bridge caused by the pattern fault of the word line can be inhibited.

In addition, the invention can minimize formation of topology between the area having the high pattern density and the area having the low pattern density after patterning the metal layer to prevent an attack of the semiconductor device during subsequent processing.

Although the invention has been described with reference to a number of illustrative embodiments thereof, numerous modifications and other embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses may also be apparent to those skilled in the art.

What is claimed is:

1. A method of manufacturing a semiconductor device, comprising:
forming a conductive layer on a semiconductor substrate;
forming a metal layer on the conductive layer;
performing a first etching process to pattern the metal layer on a first area to form first metal layer patterns at first intervals until the conductive layer of the first area is exposed;
performing a second etching process to form an etching-obstructing layer on the first area and patterning the metal layer on a second area to form second metal layer patterns at second intervals until the conductive layer of the second area is exposed, the second intervals being narrower than the first intervals;
removing the etching-obstructing layer; and
removing an exposed area of the conductive layer to form a conductive pattern.

2. The method of manufacturing a semiconductor device of claim 1, wherein the metal layer comprises a metal silicide layer.

3. The method of manufacturing a semiconductor device of claim 2, wherein the metal silicide layer comprises a tungsten silicide (WSiₓ) layer.

4. The method of manufacturing a semiconductor device of claim 1, wherein the conductive layer comprises a polysilicon layer.

5. The method of manufacturing a semiconductor device of claim 1, wherein the metal layer remains on the second area on which the second metal layer patterns are formed at second intervals after the first etching process.

6. The method of manufacturing a semiconductor device of claim 4, wherein the etching obstruction layer comprises a silicon oxide (SiO₂) layer formed by a reaction of the polysilicon layer with oxygen (O₂).

7. The method of manufacturing a semiconductor device of claim 1, comprising performing the second etching process under conditions of pressure of 4 mT to 10 mT, source power of 500 W to 1,200 W, bias power of 40 W to 200 W, oxygen (O₂) at a flow rate of 40 standard cubic centimeter per minute (sccm) to 200 sccm, nitrogen trifluroride (NF₃) at a flow rate of 20 sccm to 80 sccm and lower than the flow rate of oxygen, and chlorine (Cl₂) at a flow rate of 40 sccm to 120 sccm.

8. The method of manufacturing a semiconductor device of claim 7, wherein the second etching process further utilizes nitrogen (N₂) at a flow rate of 100 sccm to 200 sccm and argon at a flow rate of 50 sccm to 200 sccm.

9. The method of manufacturing a semiconductor device of claim 1, comprising removing the etching-obstructing layer by an etching recipe having an etching selection ratio with respect to the etching-obstructing layer, which is higher than that with respect to the conductive layer.

10. The method of manufacturing a semiconductor device of claim 1, further comprising forming a gate insulating layer between the conductive layer and the semiconductor substrate.

11. A method of manufacturing a flash memory device, comprising:
providing a semiconductor substrate on which a tunnel oxide layer, a first conductive layer, and a second conductive layer, are stacked;
forming a metal layer on the second conductive layer;
performing a first etching process for patterning the metal layer on a first area to form first metal layer patterns at first intervals until the second conductive layer of the first area is exposed;
performing a second etching process to form an etching-obstructing layer on the first area and patterning the metal layer on a second area to form second metal layer patterns at second intervals until the second conductive layer of the second area is exposed, the second intervals being narrower than the first intervals;
removing the etching-obstructing layer;
removing an exposed area of the second conductive layer to form a second conductive layer pattern;
patterning the dielectric layer; and
patterning the first conductive layer to form a first conductive layer pattern.

12. The method of manufacturing a flash memory device of claim 11, wherein the first conductive layer and the second conductive layer comprise polysilicon layers.

13. The method of manufacturing a flash memory device of claim 11, wherein the metal layer comprises a metal silicide layer.

14. The method of manufacturing a flash memory device of claim 13, wherein the metal silicide layer comprises a tungsten silicide (WSiₓ) layer.

15. The method of manufacturing a flash memory device of claim 1I1 wherein the metal layer remains on the second area on which the metal layer patterns are formed at second intervals after the first etching process.

16. The method of manufacturing a flash memory device of claim 15, wherein the first area on which the metal layer patterns are formed at first intervals is a predetermined area for forming word lines and the second area on which the metal layer patterns are formed at second intervals is a predetermined area for forming select lines.

17. The method of manufacturing a flash memory device of claim 12, wherein the etching obstruction layer comprises a silicon oxide (SiO₂) layer formed by a reaction of the polysilicon layer with oxygen (O₂).

18. The method of manufacturing a flash memory device of claim 11, comprising performing the second etching process under conditions of pressure of 4 mT to 10 mT, source power of 500 W to 1,200 W, bias power of 40 W to 200 W, oxygen (O₂) at a flow rate of 40 standard cubic centimeter per minute (sccm) to 200 sccm, nitrogen trifluroride (NF₃) at a flow rate of 20 sccm to 80 sccm and less than the flow rate of oxygen, and chlorine (Cl₂) at a flow rate of 40 sccm to 120 sccm.

19. The method of manufacturing a flash memory device of claim 18, wherein the second etching process further utilizes nitrogen (N₂) at a flow rate of 100 sccm to 200 sccm and argon (Ar) at a flow rate of 50 sccm to 200 sccm.

20. The method of manufacturing a flash memory device of claim 11, comprising removing the etching-obstructing layer by an etching recipe having an etching selection ratio with respect to the etching-obstructing layer, which is higher than that with respect to the second conductive layer.

21. The method of manufacturing a flash memory device of claim 11, wherein the dielectric layer comprises a stack layer comprising an oxide layer, a nitride layer, and an oxide layer.

22. The method of manufacturing a flash memory device of claim 11, comprising patterning the second conductive layer by an etching recipe having an etching selection ratio with respect to the second conductive layer, which is higher than that with respect to the oxide layer.

23. The method of manufacturing a flash memory device of claim 11, further comprising forming a gate mask pattern on the metal layer, the gate mask pattern having a stack structure comprising a first hard mask pattern, an amorphous carbon layer pattern, and a second hard mask pattern.

24. The method of manufacturing a flash memory device of claim 23, comprising patterning the metal layer, the second conductive layer, the dielectric layer, and the first conductive layer through an etching process in which the amorphous carbon layer pattern is used as the etching mask, or patterning the second conductive layer, the dielectric layer and the first conductive layer through an etching process in which the first hard mask pattern is used as the etching mask, after removing the amorphous carbon layer pattern.
